(19) United States
(12) Patent Application Publication
(10) Pub. No.: US 2018/0069098 A1
(43) Pub. Date: Mar. 8, 2018

(54) OXIDE TFT AND METHOD OF FORMING THE SAME

(71) Applicant: Shenzhen China Star Optoelectronics Technology Co., Ltd., Shenzhen, Guangdong (CN)

(72) Inventor: Yong DENG, Shenzhen, Guangdong (CN)

(73) Assignee: Shenzhen China Star Optoelectronics Technology Co. , Ltd., Shenzhen, Guangdong (CN)

(21) Appl. No.: 15/115,638

(22) PCT Filed: May 26, 2016
(86) PCT No.: PCT/CN2016/083511

§ 371 Date: Jul. 29, 2016

(30) Foreign Application Priority Data
Feb. 25, 2016 (CN) 201610105505.3

(51) Int. Cl. H01L 29/66; H01L 21/77; H01L 29/786; H01L 21/02; H01L 21/3065

(52) U.S. Cl. CPC H01L 29/66757; H01L 21/77; H01L 21/3065; H01L 21/0243; H01L 29/7869

(57) ABSTRACT

The present disclosure proposes an oxide TFT and its forming method. The method includes providing a substrate, forming an active layer on top of the substrate, and performing plasma surface treatment on the active layer so to get an active layer with roughness smaller than 10 nm. The deposited active layer has high roughness and defects. However, plasma surface treatment is performed on the active layer so to reasonably control types of gas ions selected, and technical parameters such as the energy and angle of ion bombardment, so to effectively press the actively layer. The pressing force can be broken down as a vertical force and a horizontal force, and it can polish the roughness and defects on the surface of the oxide semi-conductor layer, while enhancing the adhesion of the oxide semi-conductor layer.

### BACKGROUND OF THE INVENTION

### 1. Field of the Invention

The present invention relates to fields of wafer fabrication and display technology, and more specifically, to an oxide thin-film transistor (TFT) and a method of forming the same.

### 2. Description of the Prior Art

TFT liquid crystal flat-panel display is a kind of active matrix liquid crystal displays (LCDs). Each liquid crystal pixel on an active matrix LCD is driven by TFTs integrated behind the pixel. TFT has significant influence on responsiveness and color trueness of LCDs, thus it is an important component to this kind of LCDs. Commonly-seen TFT drives are mainly categorized as amorphous silicon (a-Si) TFT and low-temperature polycrystalline silicon (LTPS), to which an indium gallium zinc oxide (IGZO) TFT belongs. Given that IGZO has several advantages such as high charge carrier mobility, good stability and evenness, and are easy to prepare, it has become an emerging technology in the field of LCD as a hot topic to study.

Studies in the field of LCD about how IGZO TFTs improve performance mainly focus on the selection of a TFT structure, improvement of an interface between a gate insulator (GI) and an IGZO layer, improvement of circumstances in which the IGZO layer deposits, and control of annealing temperature and storage circumstances. An IGZO film layer, the core structure of an IGZO TFT, forms its film with a physical vapor deposition (PVD) facility in a low temperature. From the fact that the PVD facility forms a film in a low temperature, it can be inferred that the IGZO film layer has lower quality, which is mostly shown by more internal defects, poorer film adhesion, and higher roughness.

Currently, the IGZO film layer in mass-produced IGZO TFTs is thinner, around 50nm. However, there is a 1-10 mn thick roughness on its surface. Carriers are prone to Coulomb force imposed by atomic groups on the surface when transmitting through the IGZO film layer. And, the carriers are more likely to be captured by defects in the IGZO film layer, leading to electrical deterioration of IGZO TFTs. Therefore, it is necessary to improve the existing IGZO TFT manufacturing technology so to optimize the quality of IGZO film layers.

### SUMMARY OF THE INVENTION

To overcome the insufficiency in the existing technology, an objective of the present invention is to provide an oxide TFT and a method of forming the same, in the hopes to improve film quality of an active layer, and get a TFT structure that has better performance.

The present invention provides a method of forming an oxide TFT. The method comprises following steps:

providing a substrate;

forming an active layer on the substrate;

performing plasma surface treatment on the active layer, whose roughness is less than 10 nm.

Furthermore, the active layer is an IGZO film layer.

Preferably, the roughness of the active layer is smaller than 6 nm.

Even more preferably, the roughness of the active layer is 1-5 nm.

Preferably, the plasma surface treatment performed on the active layer adopts one or several of following gases: oxygen, tetrafluoromethane, nitrogen and argon.

Preferably, a gas adopted in the plasma surface treatment of the active layer is oxygen.

Furthermore, the power density of the plasma surface treatment of the active layer is 0.2-0.5 W/cm², meaning that the power density can be any value within the range, such as 0.2 W/cm², 0.25 W/cm², 0.28 W/cm², 0.3 W/cm², 0.34 W/cm², 0.38 W/cm², 0.4 W/cm², 0.42 W/cm², 0.45 W/cm² or 0.5 W/cm².

Preferably, the power density is 0.34 W/cm².

Furthermore, the ion bombardment angle adopted in the plasma surface treatment of the active layer is 0°-180°, meaning that the ion bombardment angle can be any value within the range, such as 0°, 30°, 60°, 90°, 120°, 150° or 180°.

Preferably, the ion bombardment angle adopted in the plasma surface treatment of the active layer is 0°-90°

Furthermore, the step of forming an active layer on the substrate comprises: forming a gate on the substrate; forming a gate insulator on the gate; forming an active layer on the gate insulator.

Furthermore, the gate is encompassed in the gate insulator.

Furthermore, undertaking photolithography with the active layer after the plasma surface treatment is completed.

Furthermore, the step of undertaking photolithography with the active layer comprise: forming a photoresist pattern on the active layer; etching the active layer with the photoresist pattern so to get a patterned active layer.

Furthermore, forming a gate and a drain separately on the active layer after it is photolithographed. Forming a passivation layer on the active layer, the source and the drain. Forming a contact hole on the passive layer to partially expose the drain.

Furthermore, forming pixel electrodes, which can contact the drain through the contact hole.

On a second aspect, the present invention provides a TFT produced by the abovementioned forming method. The oxide TFT is disposed with a substrate and an active layer on top. The roughness of the active layer is smaller than 10 nm through performing plasma surface treatment on the active layer.

Furthermore, the active layer is an IGZO film layer.

Preferably, the roughness of the active layer is smaller than 6 nm.

Even more preferably, the roughness of the active layer is 1-5 nm.

Preferably, the plasma surface treatment performed on the active layer adopts one or several of following gases: oxygen, tetrafluoromethane, nitrogen and argon.

Preferably, a gas adopted in the plasma surface treatment of the active layer is oxygen.

Furthermore, the power density of the plasma surface treatment of the active layer is 0.2-0.5 W/cm², meaning that the power density can be any value within the range, such as 0.2 W/cm², 0.25 W/cm², 0.28 W/cm², 0.3 W/cm², 0.34 W/cm², 0.38 W/cm², 0.4 W/cm², 0.42 W/cm², 0.45 W/cm² or 0.5 W/cm².

Preferably, the power density is 0.34 W/cm².

Furthermore, the ion bombardment angle adopted in the plasma surface treatment of the active layer is 0°-180°, meaning that the ion bombardment angle can be any value within the range, such as 0°, 30°, 60°, 90°, 120°, 150° or 180°.

Preferably, the ion bombardment angle adopted during the plasma surface treatment of the active layer is 0°-90°. Most preferably, the ion bombardment angle adopted during the plasma surface treatment of the active layer is 90°.

Furthermore, the oxide TFT includes a gate on the substrate and a gate insulator on the substrate and the gate. The gate insulator is beneath the active layer.

Furthermore, the gate is encompassed in the gate insulator.

Furthermore, undertaking photolithography with the active layer after the plasma surface treatment is completed.

Furthermore, the step of undertaking photolithography with the active layer comprise: forming a photoresist pattern on the active layer; etching the active layer with the photoresist pattern so to get a patterned active layer.

Furthermore, the oxide TFT also comprises a source and grain, disposed separately on top of the active layer. A passivation layer is disposed on top of the source, the drain and the active layer. The passivation layer is disposed with a contact hole that partially exposes the drain.

Furthermore, the oxide TFT includes a pixel electrode connected to the drain through the contact hole.

In the existing technology, plasma treatment is usually applied to etching or doping. One of the technical criteria of plasma treatment is that ions must have larger energy to conduct ion bombardment, which lead to a certain extent of damage on the surface of the corresponding film. However, the present invention adopts ions of a suitable level of energy to conduct ion bombardment on the surface of the IGZO film layer. It polishes the IGZO film layer and improves the performance of the IGZO TFT.

In the present invention, the deposited active layer has high roughness and defects. However, plasma surface treatment is performed on the active layer so to reasonably control types of gas ions selected, and technical parameters such as the energy and angle of ion bombardment, so to effectively press the actively layer. The pressing force can be broken down as a vertical force and a horizontal force, and it can polish the roughness and defects on the surface of the oxide semi-conductor layer, while enhancing the adhesion of the oxide semi-conductor layer.

### BRIEF DESCRIPTION OF THE DRAWINGS

FIGS. 1-8 illustrate a process of forming an oxide thin film transistor according to a preferred embodiment of the present invention.

FIG. 9 shows a comparison of a surface of an active layer before and after plasma treatment is performed.

FIG. 10 shows a roughness test conducted to active layers of TFTs formed of the present embodiment.

FIG. 11 shows a roughness test conducted to active layers of TFTs formed of the comparative example.

FIG. 12 shows an electrical performance test conducted to TFTs formed of the present embodiment.

FIG. 13 shows an electrical performance test conducted to TFTs formed of the comparative example.

### DETAILED DESCRIPTION OF PREFERRED EMBODIMENTS

Embodiment

An embodiment of the present invention provides a method of forming an oxide TFT, comprising following steps:

A substrate 100 is provided, as shown in FIG. 1. A gate 200 deposited on the substrate 100, and a patterned gate 200 is made through photolithographing and etching the gate 200.

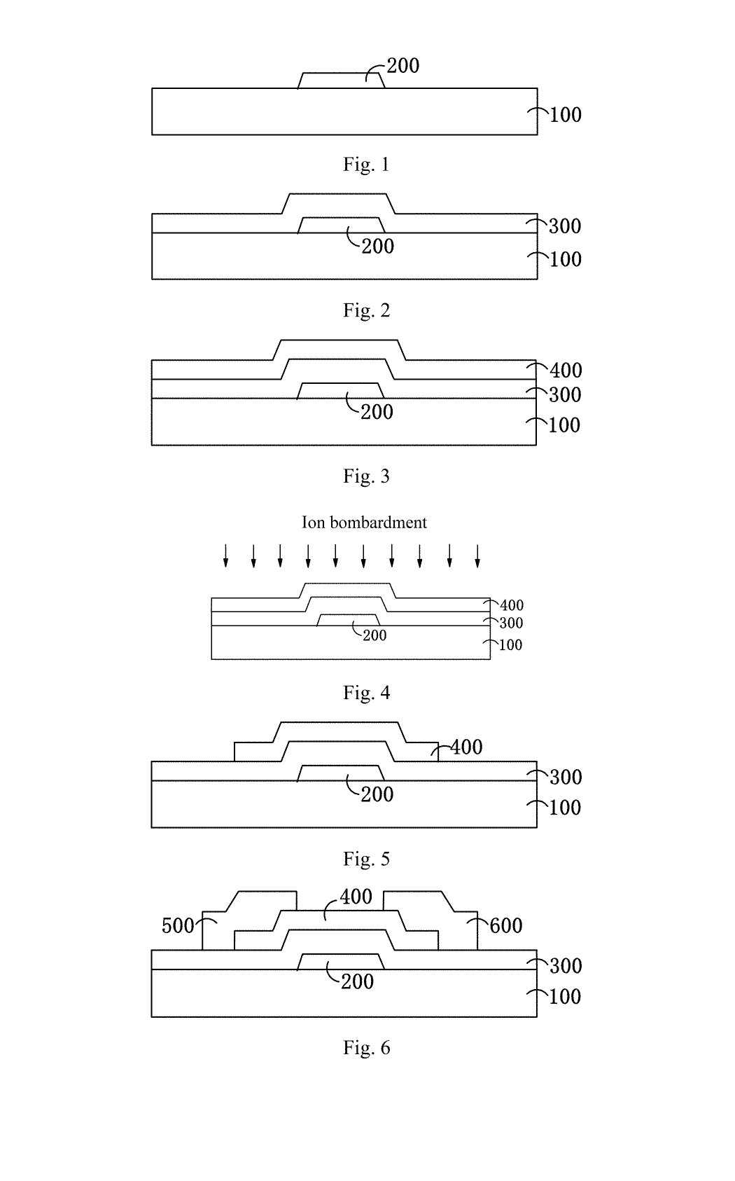

A gate insulator 300 is deposited on the patterned gate 200 and the substrate 100, as shown in FIG. 2. The gate insulator 300 encompasses the gate 200.

PVD to deposit an active layer 400 is undertaken on top of the gate insulator 300, as shown in FIG. 3. The active layer is an IGZO film layer.

Plasma surface treatment is performed on the active layer 400, as shown in FIG. 4. Oxygen with a power density at 0.34 W/cm2 is adopted to conduct ion bombardment to the active layer 400. The ion bombardment angle is 0°-90°, thus the roughness of the active layer is 1-5 nm.

Conducting photolithography and etching to the active layer 400 that has seen plasma surface treatment, as shown in FIG. 5. More specifically, forming photoresist patterns on the active layer and etching the active layer with the photoresist patterns, so to get a patterned active layer 400.

A source 500 and a drain 600 are deposited on top of the patterned active layer 400, as shown in FIG. 6. The source 500 and drain 600 are disposed separately: the source 500 on the left of the active layer 400 and the drain 600 on the right.

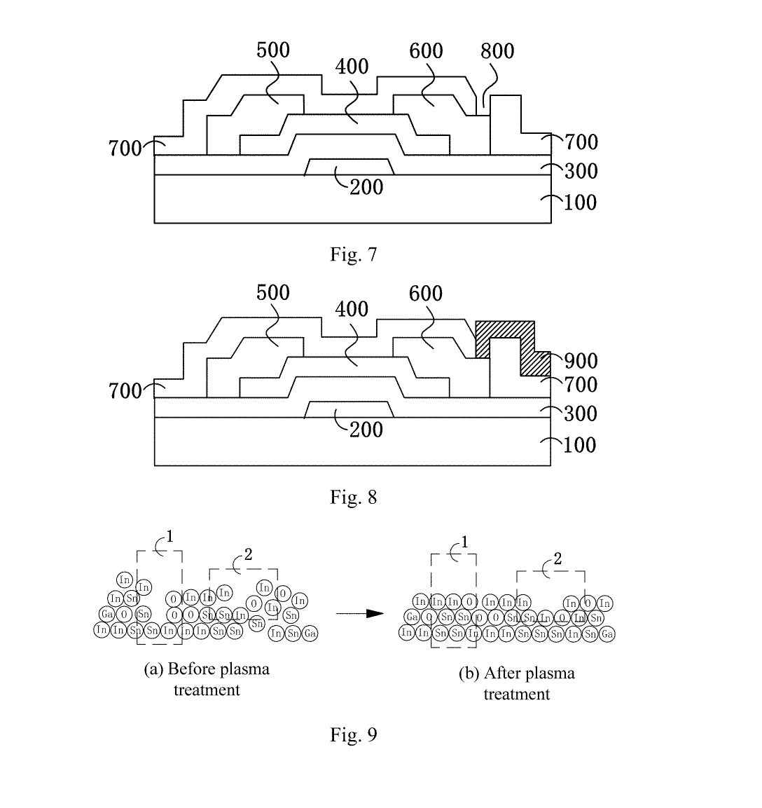

A passivation layer 700 is deposited on the source 500, drain 600 and active layer 400, as shown in FIG. 7. A contact hole 800 is formed on top of the passivation layer 700 where it corresponds to the drain (i.e. the right-hand side of the passivation layer in FIG. 7), so that the contact hole 800 goes through the passivation layer 700.

A pixel electrode 900 is formed in the oxide TFT, as shown in FIG. 8. The pixel electrode is an indium tin oxide (ITO) film layer. The pixel electrode 900 contacts the drain 600 through the contact hole 800.

The present embodiment further provides an oxide TFT formed by the abovementioned forming method. Please refer to FIG. 8 for a sectional view of the TFT's structure. The oxide TFT comprises a substrate 100 at the bottom, a patterned gate 200 disposed on top of the substrate 100, and a gate insulator 300 on top of the substrate 100 and the gate 200, with the gate insulator 300 encompassing the patterned gate 200. A patterned active layer 400, an IGZO film layer, is disposed on top of the gate insulator 300. On the surface of the active layer, a source 500 is disposed on the left and a drain 600 is disposed on the right. A passivation layer 700 is disposed on top of the source 500, the drain 600 and the active layer 400. A contact hole 800, exposing part of the drain 600, is disposed on the right-hand area of the passivation layer 700 and goes through the passivation layer. A pixel electrode 900, an ITO film layer, is also disposed in the oxide TFT. The pixel electrode 900 contacts the drain 600 through the contact hole 800.

The oxide TFT formed by the forming method of the present embodiment has an active layer whose roughness is 1-5 nm. In the present embodiment, the active layer (i.e. the IGZO film layer) is deposited and formed on the gate insulator by using PVD facilities in a low temperature environment. At the moment when the active layer is formed with the PVD facilities, as shown by the structure in FIG. 9(a), it has more internal defects and high roughness. Area 1 and area 2 are areas where the active layer has high roughness and defects. When ions of a suitable level of energy bombard the surface of the active layer, the bombardment produces a pressing force, which can be broken down as a vertical force and a horizontal force. The pressing force polishes the active layer, as shown by the structure in FIG. 9(b). After the active layer is polished by the ion bombardment, the roughness and defects on its surface are optimized, producing a structure that enhances its adhesion.

### COMPARATIVE EXAMPLE

Differences between a comparative example and the abovementioned embodiment lie in that after the active layer is deposited on the gate insulator, it is directly photolithographed and etched without undergoing a plasma surface treatment first.

Performance Test

1. Roughness Test of the Active Layer

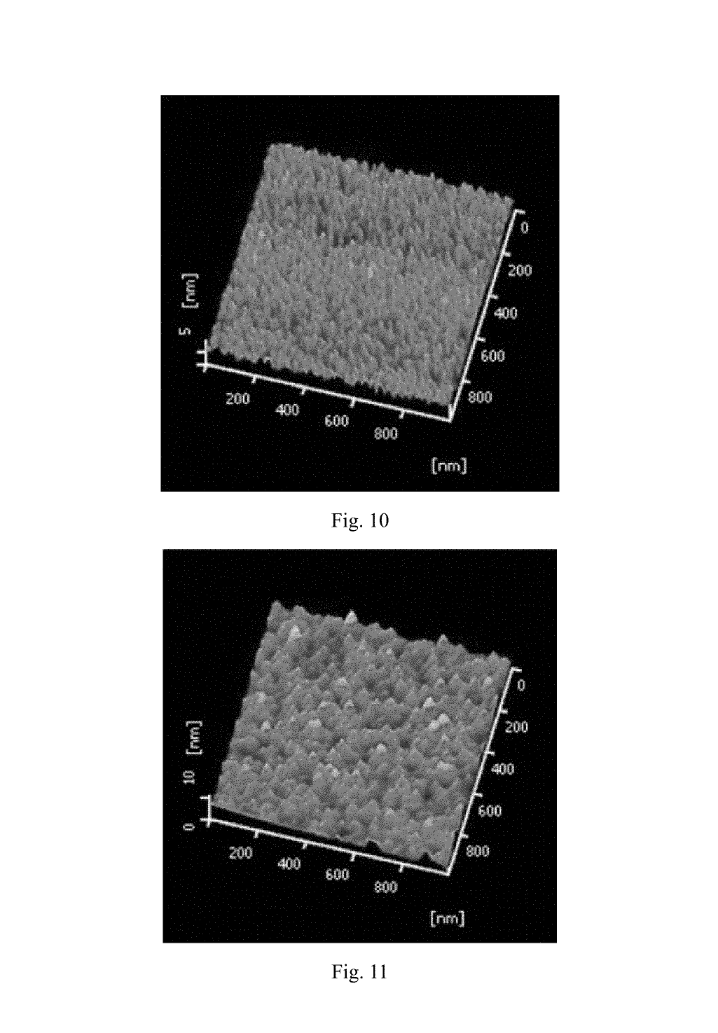

A roughness test is conducted to active layers of TFTs formed by applying the embodiment and the comparative example respectively. Results of the test are shown in FIG. 10 and FIG. 11. The roughness of the active layer of TFTs formed by the embodiment is 1-5 nm thick, and the particles on the surface of the active layer are smaller. It implies that through ion bombardment, larger particles in the active layer are crushed. The roughness of the active layer of TFTs formed by the comparative example is 1-10 nm thick, and the particles on the surface of the active layer are larger.

2. Electrical Performance Test

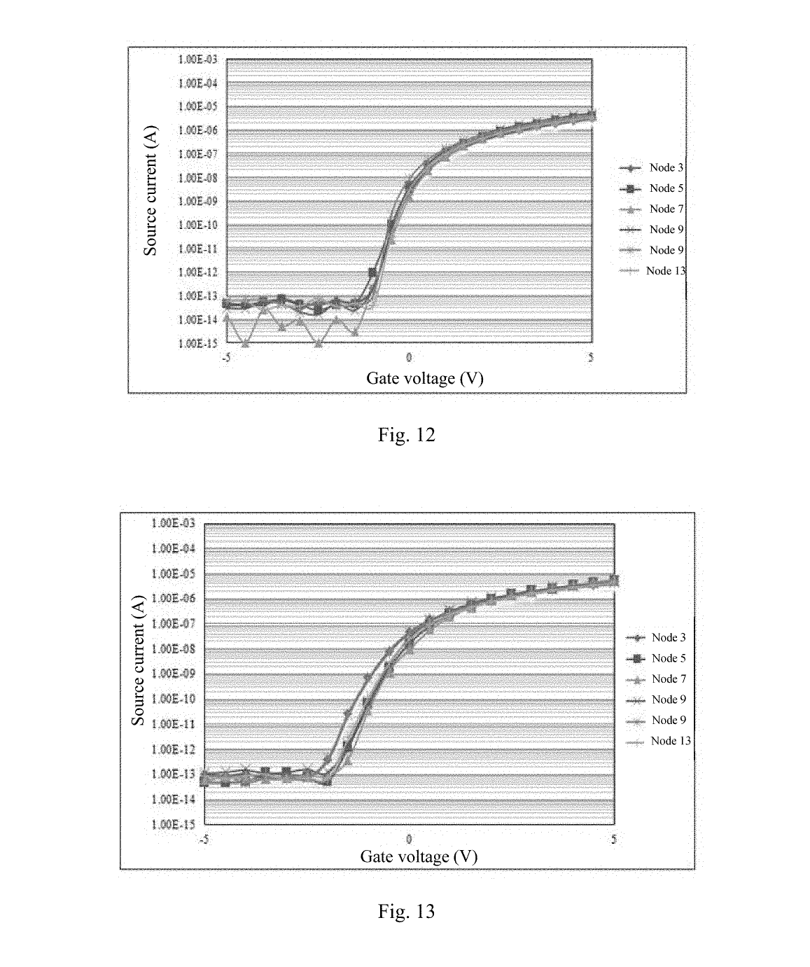

An electrical performance test is conducted to TFTs formed by applying the embodiment and the comparative example respectively. Results of the test are shown in FIG. 12 and FIG. 13. They imply that TFTs of the embodiment has better sub-domain properties and lower leakage on individual points. Meanwhile, TFTs of the comparative example do not have good sub-domain properties.

Understandably, the above text only explains the main structure of the TFTs. The abovementioned device can further include other standard functions and structures, on which the present invention does not elaborate.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of forming an oxide thin-film transistor (TFT), comprising:
providing a substrate; and
forming an active layer on top of the substrate, and performing plasma surface treatment on the active layer so to get an active layer with roughness smaller than 10 nm.

2. The method of claim 1, wherein the active layer is an indium gallium zinc oxide (IGZO) film layer.

3. The method of claim 1, wherein the plasma surface treatment performed on the active layer adopts one or several of following gases: oxygen, tetrafluoromethane, nitrogen and argon.

4. The method of claim 1, wherein the plasma surface treatment performed on the active layer adopts a power density ranging from 0.2 to 0.5 W/cm².

5. The method of claim 1, wherein the plasma surface treatment performed on the active layer adopts an ion bombardment angle ranging from 0° to 180°.

6. The method of claim 1, wherein a step of forming the active layer on the substrate comprises:
forming a gate on the substrate;
forming a gate insulator on the substrate and the gate; and
forming an active layer on the gate insulator.

7. The method of claim 2, wherein a step of forming the active layer on the substrate comprises:
forming a gate on the substrate;
forming a gate insulator on the substrate and the gate; and
forming an active layer on the gate insulator.

8. The method of claim 3, wherein a step of forming the active layer on the substrate comprises:
forming a gate on the substrate;
forming a gate insulator on the substrate and the gate; and
forming an active layer on the gate insulator.

9. The method of claim 4, wherein a step of forming the active layer on the substrate comprises:
forming a gate on the substrate;
forming a gate insulator on the substrate and the gate; and
forming an active layer on the gate insulator.

10. The method of claim 5, wherein a step of forming the active layer on the substrate comprises:
forming a gate on the substrate;
forming a gate insulator on the substrate and the gate; and
forming an active layer on the gate insulator.

11. The method of claim 1, wherein the active layer is photolithographed after it has undergone the plasma surface treatment.

12. The method of claim 2, wherein the active layer is photolithographed after it has undergone the plasma surface treatment.

13. The method of claim 3, wherein the active layer is photolithographed after it has undergone the plasma surface treatment.

14. The method of claim 4, wherein the active layer is photolithographed after it has undergone the plasma surface treatment.

15. The method of claim 1, wherein after the active layer is photolithographed, the method further comprises:
forming a source and a drain separately on the active layer;
forming a passivation layer on the active layer, the source and the drain; and
forming a contact hole on the passivation layer to partially expose the drain.

16. The method of claim 2, wherein after the active layer is photolithographed, the method further comprises:
forming a source and a drain separately on the active layer;
forming a passivation layer on the active layer, the source and the drain; and
forming a contact hole on the passivation layer to partially expose the drain.

17. The method of claim 3, wherein after the active layer is photolithographed, the method further comprises:
forming a source and a drain separately on the active layer;
forming a passivation layer on the active layer, the source and the drain; and
forming a contact hole on the passivation layer to partially expose the drain.

18. The method of claim 4, wherein after the active layer is photolithographed, the method further comprises:
forming a source and a drain separately on the active layer;
forming a passivation layer on the active layer, the source and the drain; and
forming a contact hole on the passivation layer to partially expose the drain.

19. An oxide thin film transistor (TFT) comprising a substrate and an active layer thereon, wherein plasma surface treatment is performed on the active layer so that the roughness of the active layer is smaller than 10 nm.

20. The oxide TFT of claim 19, further comprising a gate and a gate insulator disposed between the substrate and the active layer, with the gate disposed on top of the substrate, and the gate insulator disposed on top of the substrate and the gate, but underneath the active layer.
